(19) United States
(12) Patent Application Publication
(10) Pub. No.: US 2016/0052018 A1
(43) Pub. Date: Feb. 25, 2016

(54) PIEZOELECTRIC DEVICE AND ELECTRONIC DEVICE INCLUDING THE SAME

(71) Applicant: INNOCHIPS TECHNOLOGY CO., LTD., Ansan-Si (KR)

(72) Inventors: In Kil PARK, Seongnam-Si (KR); Tae Hyung NOH, Siheung-Si (KR); Sung Cheol PARK, Ansan-Si (KR); Young Sul KIM, Seoul (KR); Kyung Seob YOON, Suwon-Si (KR); Hee Seob SHIN, Siheung-Si (KR); In Seob JUNG, Ansan-Si (KR)

(21) Appl. No.: 14/710,572

(22) Filed: May 12, 2015

(30) Foreign Application Priority Data
Aug. 19, 2014 (KR) 10-2014-0107855

(51) Int. Cl. B06B 1/06; H01L 41/09

(52) U.S. Cl. CPC B06B 1/06; H01L 41/09

(57) ABSTRACT

Provided is a piezoelectric device including at least two piezoelectric plates configured to include at two contact points, wherein the at least two piezoelectric plates include at least two resonant frequencies. The piezoelectric device in a wearable device operates as at least any one of a piezoelectric sound device and a piezoelectric vibration device.

### CROSS-REFERENCE TO RELATED APPLICATION

This application claims priority to Korean Patent Application No. 10-2014-0107855 filed on Aug. 19, 2014 and all the benefits accruing therefrom under 35 U.S.C. §119, the contents of which are incorporated by reference in their entirety.

### BACKGROUND

The present disclosure relates to a piezoelectric device, and more particularly, to a piezoelectric device available as a piezoelectric sound device and piezoelectric vibration device and an electronic device including the same.

A wireless call function itself such as voice or message transmission and reception is a main purpose in a typical mobile terminal. However, as recently a smart phone is developed, the wireless call function is merely a simple function and performance of various functions such as internet, applications, TV, navigation, and SNS becomes the main purpose.

Accordingly, in order to conveniently use various functions of a smart phone, as a display unit of a smart phone is enlarged and the size thereof gets larger, a user may more conveniently use a smart phone terminal with rapidly developed techniques including internet speed, operation, or pupil recognition. In addition, in the market, a smart phone terminal to which various functions are added is rapidly released due to fierce competition between companies.

However, as the display is enlarged and accordingly the size of the smart phone terminal gets larger in order to realize various functions of a smart phone, when wearing casual dress for taking a walk or exercising, it is inconvenient to carry and a robbery or loss case may occur. In addition, when possessing the smart phone in a bag, it is inconvenient to take the smart phone out of the bag for an incoming or outgoing call, or using a messaging function. There is also a limitation in that since vibration or a ring tone of the smart phone in the bag is not heard by a user, the user may not receive an incoming call or message.

In order to address that limitation, a technique enabling a device to be mounted on a human body, namely, a wearable technique is being developed. As a typical example, Korean Patent Application Laid-open Publication Nos. 10-2009-0046306 and 10-2012-0083804 respectively disclose “Band type mobile terminal” and “Mobile terminal modifiable to bracelet type”. In addition, Korean Patent Application Laid-Open Publication No. 10-2013-0054309 also discloses “Human body-mounted auxiliary mobile device assembly”. Such a typical technique enables the wearable device, namely, an auxiliary mobile device to be carried in a watch, or necklace type.

The auxiliary mobile device notifies a user of message reception with a notification sound or vibration. To this end, a speaker for generating the notification sound and an actuator for generating vibration are required to be mounted in the auxiliary mobile device. In other words, both the speaker and actuator are required to be mounted in the auxiliary mobile device. However, since the speaker and actuator are all mounted, an area occupied by them in the auxiliary device becomes large and accordingly there is a limitation in making the size of the auxiliary mobile device small.

### SUMMARY

The present disclosure provides a piezoelectric device available as at least any one of a piezoelectric sound device and piezoelectric vibration device.

The present disclosure also provides a piezoelectric device capable of generating a sound and vibration by being mounted in an electronic device and operating as at least any one of the piezoelectric sound device and piezoelectric vibration device according to an applied signal.

The present disclosure also provides an electronic device including a piezoelectric device available as at least any one of the piezoelectric sound device and piezoelectric vibration device mounted therein to reduce an area occupied by the piezoelectric device.

In accordance with an exemplary embodiment, a piezoelectric device includes at least two piezoelectric plates configured to include at two contact points, wherein the at least two piezoelectric plates include at least two resonant frequencies.

At least one intermediate plate may be disposed between the at least two piezoelectric plates and the at least two piezoelectric plates may be separated by a predetermined interval.

The at least two piezoelectric plates may include at least two shapes.

At least one first piezoelectric plate may include one surface, another surface, and side surfaces therebetween.

The at least one intermediate plate may be provided in a frame shape including an empty inner part.

At least one second piezoelectric plate may include a support plate including a shape of the intermediate plate and at least one extension plate formed from at least one area of the support plate to an inner area of the support plate.

One end portion of the extension unit contacts one surface of the support plate.

The extension plate may include a protrusion part formed on a predetermined area thereof and the protrusion part may be connected to at least one surface of the support plate.

The piezoelectric device may further include a dummy plate disposed on a predetermined area on the support plate and the extension plate is connected to a top surface or side surface of the dummy plate.

The piezoelectric device may further include a load disposed on at least one area on the extension plate.

The piezoelectric device may further include a load disposed on at least one area on the support plate.

The piezoelectric device may further include a vibration plate disposed between at least one area on the extension plate and at least one area on the support plate.

The piezoelectric device may operate as at least any one of a piezoelectric sound device or a piezoelectric vibration device according to a signal applied to the at least two piezoelectric plates.

The signal may be applied to the extension plate of the second piezoelectric plate or to the extension and support plates.

A signal is applied to the intermediate plate to vibrate the intermediate plate.

In accordance with another exemplary embodiment, an electronic device includes a piezoelectric device configured to include at least two piezoelectric plates configured to include at two contact points, wherein the at least two piezoelectric plates include at least two resonant frequencies and the piezoelectric device operates as at least any one of a piezoelectric sound device and a piezoelectric vibration device according to a signal applied to the at least two piezoelectric devices.

The electronic device may be separated from a mobile terminal body to perform an auxiliary function of the mobile terminal, and is wearable.

At least one intermediate plate may be disposed between the at least two piezoelectric plates and the at least two piezoelectric plates are separated by a predetermined interval.

The at least two piezoelectric plates may include at least two shapes.

At least a first piezoelectric plate may be provided in a plate shape, the at least one intermediate plate may be provided in a frame shape including an empty inner part.

At least one second piezoelectric plate includes a support plate including a shape of the intermediate plate and at least one extension plate formed from at least one area from the support plate to an inner area of the support plate.

The electronic device may further include a load disposed on at least one area on the extension plate.

The electronic device may further include a load disposed on at least one area on the support plate.

The electronic device may further include a vibration plate provided between at least one area of the extension plate and at least one area of the support plate.

A signal may be applied to at least any one of the extension plate and support plate of the second piezoelectric plate.

A signal may be further applied to the intermediate plate to vibrate the intermediate plate.

### BRIEF DESCRIPTION OF THE DRAWINGS

Exemplary embodiments can be understood in more detail from the following description taken in conjunction with the accompanying drawings, in which:

FIG. 1 is an exploded perspective view of a piezoelectric device according to an exemplary embodiment;

FIGS. 2 to 4 are exploded perspective views of piezoelectric devices according to other exemplary embodiments;

FIGS. 5A to 9D are plan views of piezoelectric devices according to various modification examples of an embodiment;

FIGS. 10A to 12B are graphs representing impedance and sound pressure characteristics of each part of an piezoelectric device according to an exemplary embodiment;

FIGS. 13A to 15B are graphs representing impedance and sound pressure characteristics of a piezoelectric device according to a signal application scheme according to an exemplary embodiment;

FIG. 16 is a comparison graph of sound pressure characteristic of a piezoelectric device according to a signal application scheme; and

FIG. 17 is a vibration characteristic graph of a piezoelectric device according to an exemplary embodiment.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

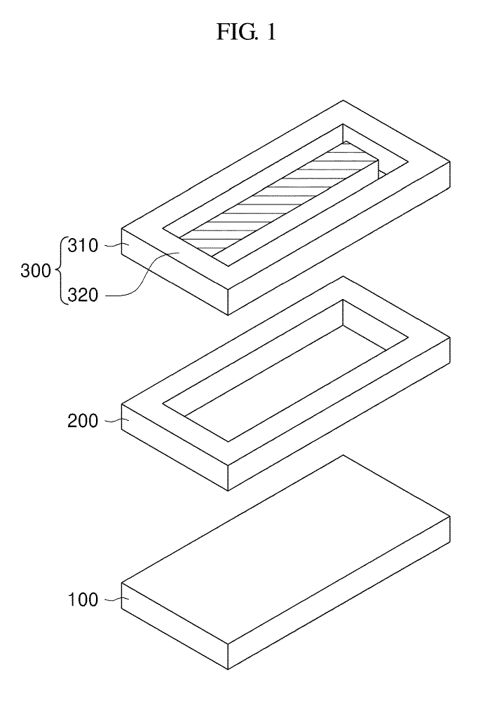

FIG. 1 is an exploded perspective view of a piezoelectric device according to an exemplary embodiment.

Referring to FIG. 1, a piezoelectric device according to an exemplary embodiment may include a first piezoelectric plate 100 having a predetermined plate form, an intermediate plate 200 disposed to contact an edge of one surface of the first piezoelectric plate 100, a second piezoelectric plate 300 disposed to make a contact on the intermediate plate 200 and having a different resonant frequency from the first piezoelectric plate 100. In other words, in the piezoelectric device according to an embodiment, the intermediate plate 200 is disposed on an edge of the first and second piezoelectric plates 100 and 300 having different resonant frequencies and the central portions of the first and second piezoelectric plates 100 and 300 are separated by a predetermined interval with the intermediate plate 200 disposed therebetween. In addition, the first and second piezoelectric plates 100 and 300 may be differed in shape.

The first piezoelectric plate 100 may be provided to have a predetermined thickness and, for example, in a rectangular plate shape. In other words, in the piezoelectric device 100, one surface and the other surface opposite to each other are provided and four side surfaces may be provided along edges of the top and bottom surfaces. The first piezoelectric plate 100 may be provided in various forms such as a square, ellipse, or polygon as well as the rectangle. The first piezoelectric plate 100 may include a substrate and a piezoelectric layer in which the substrate is formed on at least one surface. For example, the first piezoelectric plate 100 may be formed in a bimorph type in which piezoelectric layers are formed on both sides of a substrate, or in a unimorph type in which a piezoelectric layer is formed on one side of a substrate. The piezoelectric layer may be formed by stacking at least one layer, or a plurality of layers. In addition, electrodes may be respectively formed on the top and bottom portions of the piezoelectric layer. In other words, a plurality of piezoelectric layers and a plurality of electrodes may be alternately stacked to realize the first piezoelectric plate 100. The first piezoelectric plate 100 may be manufactured by forming electrodes in a frame shape on the top portion of the piezoelectric layer to stack a plurality of layers on which the electrodes are formed in this shape and then removing predetermined areas of the piezoelectric layers on which the electrodes are not formed. Here, the piezoelectric layer may be formed of a piezoelectric material, for example, PZT (Pb, Zr, Ti), NKN (Na, K, Nb), or BNT (Bi, Na, Ti)-based material. In addition, the piezoelectric layer may be polarized in different directions or an identical direction and stacked. In other words, when a plurality of piezoelectric layers are formed on one surface of a substrate, polarizations of each of the plurality of piezoelectric layers may be alternately formed in different directions or in an identical direction. Furthermore, the substrate may use a material, for example, a metal or plastics, having a characteristic that vibration may be generated while a structure in which the piezoelectric layers are stacked may be maintained. However, the first piezoelectric plate 100 may not employ a substrate of a different material from that of the piezoelectric layer. In other words, in the first piezoelectric plate 100, an unpolarized piezoelectric layer may be provided at the central portion and a plurality of piezoelectric layers polarized in different directions may be stacked at the top and bottom portions thereof. Furthermore, an electrode pattern (not illustrated) to which a driving signal is applied may be formed on one surface of the first piezoelectric plate 100, for example, a surface facing the second piezoelectric plate 300. At least two electrode patterns may be formed separately from each other and connected to an electronic device, for example, an auxiliary mobile device through connection to connection terminals (not illustrated). The first piezoelectric plate 100 may be driven as a piezoelectric sound device or a piezoelectric vibration device according to a signal applied through an electronic device, namely, AC power. For example, power having a polarity identical to a polarization direction may be applied to drive the first piezoelectric plate 100 as the piezoelectric vibration device, or power having a polarity opposite to the polarization direction may be applied to drive as the piezoelectric sound device.

The intermediate plate 200 contacts an edge of one surface of the first piezoelectric plate 100. In other words, the intermediate plate 200 is provided in an approximately rectangular frame shape having a predetermined width and an empty inner part in order to correspond to the edge of the first piezoelectric plate 100. The intermediate plate 200 may be provided in various forms such as a square, ellipse, or polygon as well as the rectangular frame shape. At this point, the intermediate plate 200 may be provided in an identical shape to or in a different shape from that of the first and second piezoelectric plates 200. For example, the first and second piezoelectric plates 100 may be provided in rectangle and the intermediate plate 200 may be prepared in square. Furthermore, the intermediate plate 200 may be provided in a smaller size than that of the first piezoelectric plate 100. In other words, the intermediate plate 200 may contact from an edge into the inside of the first piezoelectric plate 100 and accordingly the edge of the first piezoelectric plate 100 may be exposed to the outside of the intermediate plate 200. In addition, the intermediate plate 200 may have the thickness identical to or different from the first piezoelectric plate 100. The intermediate plate 200 may include a substrate and at least one piezoelectric layer formed on at least one surface of the substrate. In other words, the intermediate plate 200 may be formed in an identical stacked structure to that of the first piezoelectric plate 100. In addition, electrodes may be respectively formed on the top and bottom portions of the piezoelectric layer. In other words, a plurality of piezoelectric layers and a plurality of electrodes may be alternately stacked to realize the intermediate piezoelectric plate 200. Here, the piezoelectric layer may be polarized in different directions or an identical direction and stacked. In other words, when a plurality of piezoelectric layers are formed on at least one surface of a substrate, polarizations of each of the plurality of piezoelectric layers may be alternately formed in different directions or in an identical direction. At this point, a predetermined electrode pattern may be formed for signal application at a predetermined area. Accordingly, the intermediate plate 200 may generate vibration by a predetermined signal and accordingly be functioned as a piezoelectric sound device or a piezoelectric vibration device. However, the intermediate plate 200 may not receive a signal and then not generate the vibration, and to this end, an electrode may be formed between the piezoelectric layers and the piezoelectric layer may not be polarized.

The second piezoelectric plate 300 may contact the intermediate plate 200 and be provided thereon. In other words, the central portion of the second piezoelectric plate 300 may be separated from the central portion of the first piezoelectric plate 100 by a predetermined interval with the intermediate plate 200 disposed therebetween. At this point, the interval between the first and second piezoelectric plates 100 and 300 may be adjusted according to the thickness of the intermediate plate 200. The second piezoelectric plate 300 may be formed in a different shape from that of the first piezoelectric plate 100 and have a different resonant frequency from the first piezoelectric plate 100. For example, the second piezoelectric plate 300 may include a support plate 310 having an identical shape to the intermediate layer 200 and an extended plate 320 contacting at least one area of the support plate 310 and disposed at an area inside the support plate 310. In other words, the second piezoelectric plate 300 may include the support plate 310 having two long sides and two short sides opposite to each other in an approximately rectangular frame shape and the extension plate 320 contacting at least one area of the support plate 310 and disposed inside the support plate 310. Here, the thickness of the extension plate 320 may be identical to that of the support plate 310. In other words, the second piezoelectric plate 300 may be realized by removing an area between the extension plate 320 and the support plate 310 on the approximately rectangular plate. The thickness of the extension plate 320 may be thinner than that of the support plate 310. In other words, after the support plate 310 is formed in an identical shape to that of the intermediate plate 200 on the approximately rectangle plate, the extension plate 320 may be disposed inside the support plate 310 by bonding the extension plate 320 to at least one area on the support plate 310. Here, an area of a space between the support plate 310 and the extension plate 320 and an area of the extension plate 320 may have a ratio of 5:1 to 1:5. The resonant frequency of the second piezoelectric plate 300 may be adjusted by adjusting a ratio of an area of a space between the support plate 310 and the extension plate 320 and an area of the extension plate 320. The second piezoelectric plate 300 may be provided in various forms such as a square, ellipse, or polygon as well as the rectangle. In other words, the second piezoelectric plate 300 may be disposed in an identical shape as those of the first piezoelectric plate 100 and the intermediate layer 200. However, the second piezoelectric plate 300 may have a different shape from those of the first piezoelectric plate 100 and the intermediate layer 200. In addition, the second piezoelectric plate 300 may have the identical thickness to or a different thickness from those of the first piezoelectric plate 100 and the intermediate layer 200. For example, the first and second piezoelectric plates 100 and 300 may be formed to have the identical thickness and the intermediate plate 200 may be formed to have the different thickness from those of them. Furthermore, the second piezoelectric plate 300 may include a substrate and a piezoelectric layer formed on at least one surface of the substrate. In other words, the support plate 310 and the extension plate 320 may include a substrate and a piezoelectric layer formed on at least one surface of the substrate. For example, the second piezoelectric plate 300 may be formed in a bimorph type in which piezoelectric layers are formed on both sides of the substrate, or in a unimorph type in which a piezoelectric layer is formed on one side of the substrate. The piezoelectric layer may be formed by stacking at least one layer, or a plurality of layers. In addition, electrodes may be respectively formed on the top and bottom portions of the piezoelectric layer. In other words, a plurality of piezoelectric layers and a plurality of electrodes may be stacked to realize the second piezoelectric plate 300. The second piezoelectric plate 300 may be manufactured by forming electrodes in a shape of the support plate 310 and extension plate 320 on the top portion of the piezoelectric layer, stacking a plurality of layers on which the electrodes are formed in this shape and then removing predetermined areas of the piezoelectric layers on which the electrodes are not formed. The second piezoelectric plate 300 may be manufactured by bonding the extension plate 320 in which a plurality of piezoelectric layers, each of which has an electrode therein, are stacked to a predetermined area of the support plate 310 in which a plurality of piezoelectric plates, each of which has an electrode thereon, are stacked. In addition, the piezoelectric layers may be polarized in different directions or an identical direction and stacked. In other words, when a plurality of piezoelectric layers are formed on one surface of the substrate, polarization of each of the plurality of piezoelectric layers may be alternately formed in different directions or in an identical direction. Furthermore, the substrate may use a material, for example, a metal or plastics, having a characteristic that vibration may be generated while a structure in which the piezoelectric layers are stacked may be maintained However, the second piezoelectric plate 300 may not employ a substrate having a different material from the piezoelectric layer. In other words, in the second piezoelectric plate 300, an unpolarized piezoelectric layer may be provided at the central portion and a plurality of piezoelectric layers polarized in different directions may be stacked at the top and bottom portions thereof. Furthermore, an electrode pattern (not illustrated) to which a driving signal is applied may be formed on a predetermined area of the second piezoelectric plate 300, for example, on the top surface of the extension plate 320. At least two electrode patterns may be formed separately from each other and connected to an electronic device, for example, an auxiliary mobile device through connection to connection terminals (not illustrated). In addition, an electrode pattern (not illustrated) may be formed on a predetermined area of the support plate 310 as well as the extension plate 320, and connected to an electronic device, for example, an auxiliary mobile device through connection to connection terminals (not illustrated). The second piezoelectric plate 300 like this may be driven as a piezoelectric sound device or a piezoelectric vibration device according to a signal applied through an electronic device, namely, AC power. For example, power having a polarity identical to a polarization direction may be applied to drive the second piezoelectric plate 300 as the piezoelectric vibration device, or power having a polarity opposite to the polarization direction may be applied to drive as the piezoelectric sound device.

As described above, a piezoelectric device according to an embodiment includes a first piezoelectric plate 100, an intermediate plate 200 formed at an edge of one surface of the first piezoelectric plate 100 to have an approximate frame shape, and a second piezoelectric plate 300 including a support plate 310 disposed on the intermediate plate 200 to have an approximate frame shape, and an extension plate 320 contacting one area of the support plate 310 and disposed in the support plate 310. In other words, a piezoelectric device may include at least two piezoelectric plates 100 and 300 having at least two contact points. Here, the intermediate plate 200 contacts edges of the first and second piezoelectric plates 100 and 300 to operate as contact points of the first and second piezoelectric plates 100 and 300, and since the second piezoelectric plate 300 includes the support plate 310 and the extension plate 320, a part of the support plate 310 operates as a contact point of the extension plate 320. Accordingly, since a piezoelectric device of an embodiment has at least two contact points, the at least two piezoelectric plates 100 and 300 may have different resonant frequencies. In addition, in a piezoelectric device of an embodiment, the at least two piezoelectric plates 100 and 300 may have different shapes. Such a piezoelectric device is separated from an electronic device, for example, a smart phone to be disposed in an auxiliary mobile device performing an auxiliary function of the smart phone, namely, a wearable device mountable on a body and may operate as at least any one of a piezoelectric speaker and a piezoelectric actuator according to a signal provided from the auxiliary mobile device. In other words, the first and second piezoelectric plates 100 and 300 may selectively operate as a piezoelectric sound device or a piezoelectric vibration device at the same time, or any one of the first and second piezoelectric plates 100 and 300 may operate as the piezoelectric sound device and the other may operate as the piezoelectric vibration device. Typically, a piezoelectric actuator oscillates at a frequency of 300 Hz to generate vibration and a piezoelectric speaker oscillates at a frequency of 500 Hz or higher to output a sound. However, a piezoelectric device of an embodiment operates at a frequency of 300 Hz to 1.2 kHz to output a vibration or sound. In other words, a piezoelectric device of an embodiment is a complex device including the first and second piezoelectric plates 100 and 300 having different shapes and resonant frequencies, and applied to an electronic device such as an auxiliary mobile device to generate the sound and vibration. Accordingly, a piezoelectric device of an embodiment may function as the piezoelectric sound device or the piezoelectric vibration device, and when applied to an electronic device such as an auxiliary mobile device, may reduce an occupied area in the auxiliary mobile device in comparison to a typical device that both of sound and vibration devices are necessary. In addition, when a piezoelectric device of an embodiment is used as a piezoelectric sound device, medium and high frequency band characteristics as well as low frequency characteristic may be improved. In other words, characteristic of a frequency of 1 kHz or lower and characteristic of a frequency higher than 1 kHz may be improved.

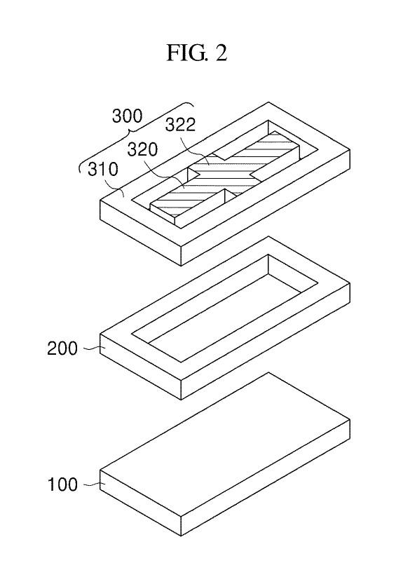

FIGS. 2 to 4 are exploded perspective views of piezoelectric devices according to other exemplary embodiments.

Referring to FIG. 2, a piezoelectric device according to another embodiment includes a first piezoelectric plate 100 having an approximately rectangular plate shape, an intermediate plate 200 formed at an edge of one surface of the first piezoelectric plate 100 to have an approximately rectangular frame shape, and a second piezoelectric plate 300 including a support plate 310 disposed on the intermediate plate 200 to have an identical shape to the intermediate plate 200 and an extension plate 320 contacting two areas of the support plate 310 and disposed in the support plate 310. In other words, the extension plate 320 of the second piezoelectric plate 300 is disposed in a space formed by the support plate 310 and two protrusion parts 322 are formed from the central portion of a long side of the extension plate 320 and contact long sides of the support plate 310. Compared to the embodiment of FIG. 1, while one short side of the extension unit 320 contacts the support plate 310 in the embodiment of FIG. 1, two long side areas of the extension plate 320 contact the support plate 310 in the other embodiment of FIG. 2.

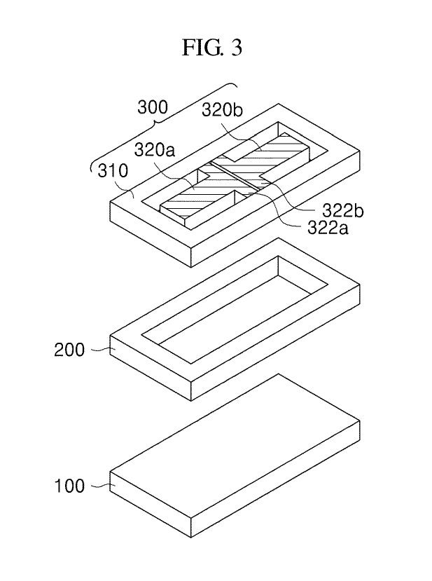

Referring to FIG. 3, a piezoelectric device according to still another embodiment includes a first piezoelectric plate 100 having an approximately rectangular plate shape, an intermediate plate 200 formed at an edge of one surface of the first piezoelectric plate 100 to have an approximately rectangular frame shape, and a second piezoelectric plate 300 including a support plate 310 disposed on the intermediate plate 200 to have an identical shape to the intermediate plate 200, and first and second extension plates 320a and 320b contacting one area of the support plate 310 and disposed in the support plate 310. In other words, the first and second extension plates 320a and 320b of the second piezoelectric plate 300 are disposed to be separated from each other at the long side central portions of the support plate 310and two area protrusion units 322a and 322b are formed from areas corresponding to the long side central portions of the support plate 310 to contact the support plate 310. Compared to the other embodiment of FIG. 2, in the still other embodiment of FIG. 3, the central portion of the area contacting the support plate 310 is cut to form first and second extension plates 320a and 320b.

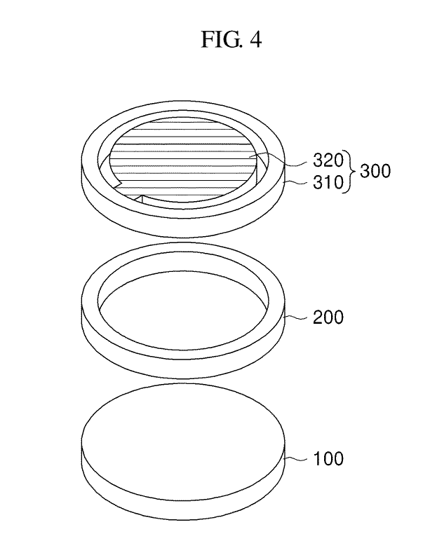

Referring to FIG. 4, a piezoelectric device according to still another embodiment includes a first piezoelectric plate 100 having an approximately circular plate shape, an intermediate plate 200 formed at an edge of a side of the first piezoelectric plate 100 to have an approximately circular frame shape, and a second piezoelectric plate 300 including a support plate 310 disposed on the intermediate plate 200 to have an identical shape to the intermediate plate 200 and an extension plate 320 contacting one area of the support plate 310 and disposed in the support plate 310. In other words, a piezoelectric device of an embodiment may be provided in a circular shape. In addition, in the second piezoelectric plate 300, the extension plate 320 is provided in a circular shape and one area of the extension plate 320 is extended to contact a predetermined area of the support plate 310.

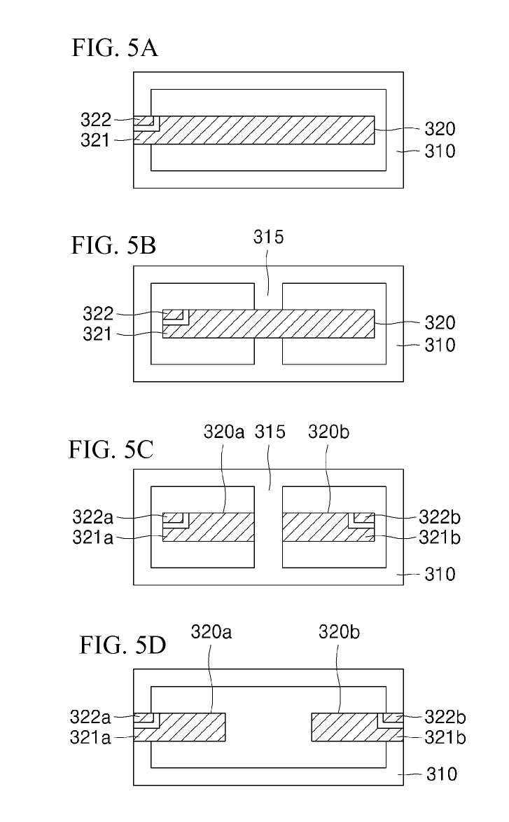

Furthermore, in the piezoelectric device of an embodiment, the shape of the second piezoelectric plate 300 may be diversely changed and accordingly various frequency characteristics can be obtained. FIGS. 5A to 5D illustrate the second piezoelectric plates according to various modification examples of an embodiment.

As illustrated in FIG. 5A, the second piezoelectric plate 300 includes a support plate 310 having an approximately rectangular frame shape and an extension plate 320 contacting one short side of the support plate 310 and disposed in the support plate 310 in a long side direction of the support plate 310. In addition, at least two electrode patterns 321 and 322 may be formed on the top surface of the extension plate 320 and AC power having different polarities may be applied to the two electrode pattern 321 and 322.

As illustrated in FIG. 5B, the second piezoelectric plate 300 includes a support plate 310 having an approximately rectangular frame shape, a dummy plate 315 disposed between predetermined areas of two opposite long sides of the support plate 310, and an extension plate 320 contacting the top surface of the dummy plate 315 and disposed in a long side direction of the support plate 310. The dummy plate 315 may be formed to have a predetermined width between, for example, central portions of two opposite long sides. Here, the dummy plate 315 may be formed to have an identical width to, or a wider or narrower width than the support plate 310. In addition, the central portion of the extension plate 320 may make a contact on the dummy plate 315. In other words, the central portion of the extension unit 320 makes a contact on the dummy plate 315 to be disposed in a space formed by the support plate 310 in a long side direction of the support plate 310. In addition, at least two electrode patterns 321 and 322 may be formed on the top surface of the extension plate 320 and AC power having different polarities may be applied to the two electrode pattern 321 and 322.

As illustrated in FIG. 5C, the second piezoelectric plate 300 may include a support plate 310 having an approximately rectangular frame shape, a dummy plate 315 disposed between predetermined areas, for example, central portions, of two opposite long sides of the support plate 310, and first and second extension plates 320a and 320b disposed in opposite directions from the dummy plates 315. In other words, the first and second extension plates 320a and 320b may be separated and contact two side surfaces or the top surface of the dummy plate 315. In addition, at least two electrode patterns 321a and 322a may be formed on the top surface of the first extension plate 320a and at least two electrode patterns 321b and 322b may also be formed on the top surface of the second extension plate 320b. AC power having different polarities may be applied to each electrode pattern.

As illustrated in FIG. 5D, the second piezoelectric plate 300 may include a support plate 310 having an approximately rectangular frame shape, and first and second extension plates 320a and 320b extended along a long side direction of the support plate 310 from two opposite short sides of the support plate 310. In other words, the first and second extension plates 320a and 320b are formed in a long side direction of the support plate 310 from the top surface of the opposite two short sides or side surfaces of the support plated 310 and disposed to be separated by a predetermined interval at the central area inside the support plate 310. Here, at least two electrode patterns 321a and 322a may be formed on the top surface of the first extension plate 320a and at least two electrode patterns 321b and 322b may also be formed on the top surface of the second extension plate 320b. AC power having different polarities may be applied to each electrode pattern.

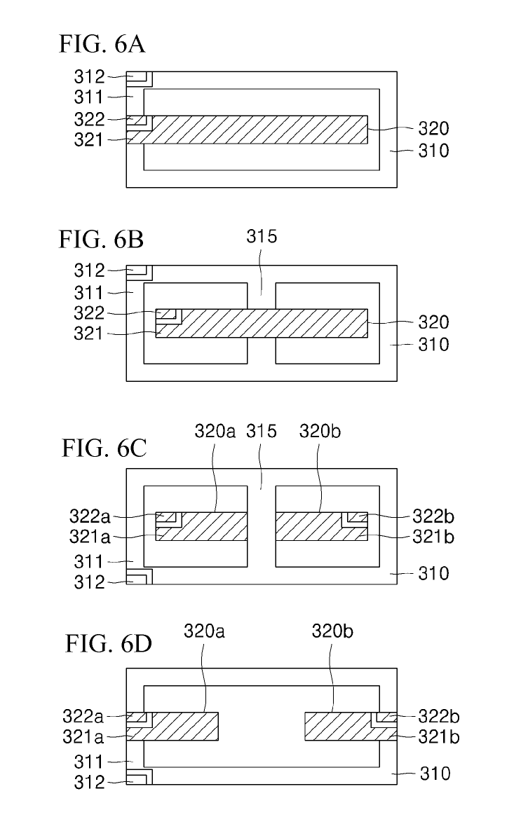

Furthermore, in a piezoelectric vibration device of an embodiment, AC power may also be applied to the support plate 310 as well as the extension plate 320 of the second piezoelectric plate 300, and accordingly frequency characteristic may be diversely changed. FIGS. 6A to 6D illustrate the second piezoelectric plate 300 according to various modification examples according to an embodiment.

As illustrated in FIG. 6A, the second piezoelectric plate 300 includes a support plate 310 having an approximately rectangular frame shape and an extension plate 320 contacting one short side of the support plate 310 and disposed in the support plate 310 in a long side direction of the support plate 310. In addition, at least two electrode patterns 311 and 312 are formed on the top surface of the support plate 310 and at least two electrode patterns 321 and 322 are formed on the top surface of the extension plate 320. AC power having different polarities may be applied to each of the electrode patterns 311 and 312 of the support plate 310 and the electrode patterns 321 and 322 of the extension plate 320.

As illustrated in FIG. 6B, the second piezoelectric plate 300 includes a support plate 310 having an approximately rectangular frame shape, a dummy plate 315 disposed between the central portions of two opposite long sides of the support plate 310, and an extension plate 320 making a contact on the dummy plate 315 and disposed in a long side direction of the support plate 310. In addition, at least two electrode patterns 311 and 312 are formed on the top surface of the support plate 310 and at least two electrode patterns 321 and 322 are formed on the top surface of the extension plate 320. AC power having different polarities may be applied to each of the electrode patterns 311 and 312 of the support plate 310 and the electrode patterns 321 and 322 of the extension plate 320.

As illustrated in FIG. 6C, the second piezoelectric plate 300 may include a support plate 310 having an approximately rectangular frame shape, a dummy plate 315 disposed between predetermined areas, for example, the central portions, of two opposite long sides of the support plate 310, and first and second extension plates 320a and 320b disposed in opposite directions from the dummy plates 315. In other words, the first and second extension plates 320a and 320b may be separated and contact two side surfaces or the top surface of the dummy plate 315 in a long side direction of the support plate 310. In addition, at least two electrode patterns 321a and 322a may be formed on the top surface of the first extension plate 320a and at least two electrode patterns 321b and 322b may also be formed on the top surface of the second extension plate 320b. AC power having different polarities may be applied to each electrode pattern. In addition, at least two electrode patterns 311 and 312 may be formed on the top surface of the support plate 310 and AC power having different polarities may be applied thereto.

As illustrated in FIG. 6D, the second piezoelectric plate 300 may include a support plate 310 having an approximately rectangular frame shape, and first and second extension plates 320a and 320b extended along a long side direction of the support plate 310 from two opposite short sides of the support plate 310. In other words, the first and second extension plates 320a and 320b are formed in a long side direction of the support plate 310 from the top surface of the opposite two short sides or side surfaces of the support plated 310 and disposed to be separated by a predetermined interval at the central area inside the support plate 310. Here, at least two electrode patterns 321a and 322a may be formed on the top surface of the first extension plate 320a and at least two electrode patterns 321b and 322b may also be formed on the top surface of the second extension plate 320b. AC power having different polarities may be applied to each electrode pattern. In addition, at least two electrode patterns 311 and 312 may be formed on the top surface of the support plate 310 and AC power having different polarities may be applied thereto.

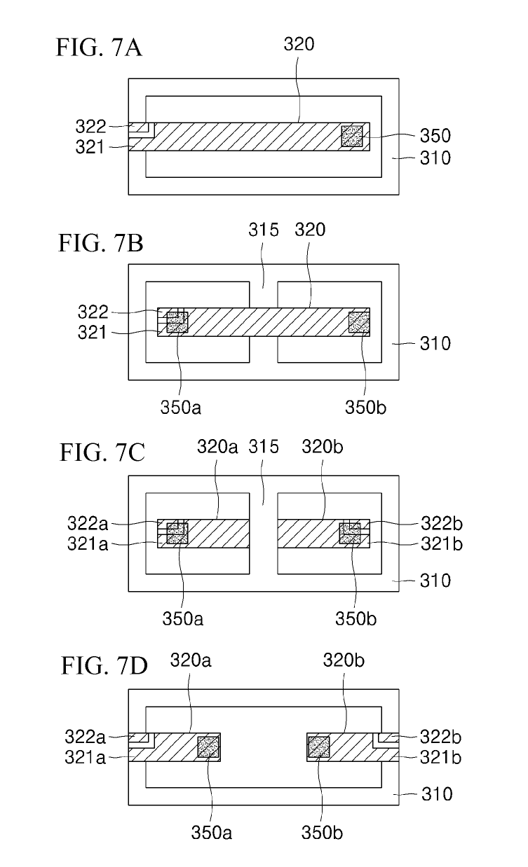

In addition, in a piezoelectric device of an embodiment, a load is disposed on at least one area of the second piezoelectric plate 300 to increase a vibration force and accordingly frequency characteristic may be diversely changed. Weight, position, and form of the load may be diversely modified and accordingly various vibration forces may be realized. FIGS. 7A to 7D illustrate the second piezoelectric plate 300 according to various modification examples according to an embodiment.

As illustrated in FIG. 7A, the second piezoelectric plate 300 may include a support plate 310 having an approximately rectangular frame shape and an extension plate 320 contacting a predetermined area of one short side of the support plate 310 and disposed in a long side direction of the support plate 310, and a load 350 may be disposed on one end portion of the extension plate 320, which does not contact the support plate 310. In addition, at least two electrode patterns 320 and 321 may be formed on the top surface of the extension plate 320 and AC power having different polarities may be applied thereto.

As illustrated in FIG. 7B, the second piezoelectric plate 300 includes a support plate 310 having an approximately rectangular frame shape and having a dummy plate 315 formed between one long side and the other long side opposite to each other, an extension plate 320 making a contact on the dummy plate 135 and disposed in a long side direction of the support plate 310, and loads 350a and 350b respectively disposed on two opposite end portions of the extension plate 320. In other words, the load 350a may be disposed on an area to which AC power is applied.

As illustrated in FIG. 7C, the second piezoelectric plate 300 includes a support plate 310 having an approximately rectangular frame shape and having a dummy plate 315 formed between one long side and the other long side opposite to each other, first and second extension plates 320a and 320b contacting two side surfaces of the dummy plate 315 and disposed in a long side direction of the support plate 310, and loads 350a and 350b disposed on two opposite end portions of the first and second extension plate 320a and 320b, which do not contact the dummy plate 315. In other words, the loads 350a and 350b may be disposed on areas of the first and second 320a and 320b, to which AC power is applied.

As illustrated in FIG. 7D, the second piezoelectric plate 300 includes a support plate 310 having an approximately rectangular frame shape, first and second extension plates 320a and 320b formed in a long side direction of the support plate 310 from two opposite short sides of the support plate 310 and separated by a predetermined interval at the central area inside the support plate 310, and loads 350a and 350b formed on end portions of the first and second extension plates 320a and 320b. In other words, the loads 350a and 350b may be disposed on areas of the first and second 320a and 320b, to which AC power is applied.

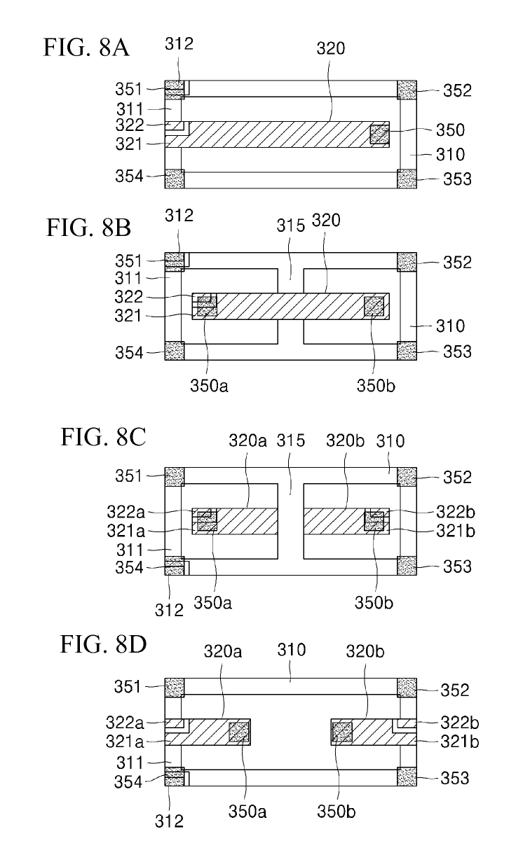

In addition, the load may also be formed on predetermined areas of the support plate 310 as well as on the extension plate 320, and FIGS. 8A to 8D illustrate the second piezoelectric plate 300 on which the loads are formed on the support pate 310 and the extension plate 320.

As illustrated in FIG. 8A, the second piezoelectric plate 300 may include a support plate 310 having an approximately rectangular frame shape, an extension plate 320 disposed in a predetermined area of one short side of the support plate 310 in a long side direction of the support plate 310 in the support plate 310, and a load 350 on one end portion of the extension plate 320, which does not contact the support plate 310. In addition, a plurality of loads 351, 352, 353, and 354 are disposed at corner areas of the support plate 310.

As illustrated in FIG. 8B, the second piezoelectric plate 300 includes a support plate 310 having an approximately rectangular frame shape and having a dummy plate 315 formed between one long side and the other long side opposite to each other, an extension plate 320 making a contact on the dummy plate 135 and disposed in a long side direction of the support plate 310, and loads 350a and 350b disposed on two end portions of the extension plate 320. In addition, a plurality of loads 351, 352, 353, and 354 are disposed at corner areas of the support plate 310.

As illustrated in FIG. 8C, the second piezoelectric plate 300 includes a support plate 310 having an approximately rectangular frame shape and having a dummy plate 315 formed between one long side and the other long side opposite to each other, first and second extension plates 320a and 320b contacting two side surfaces of the dummy plate 315 and disposed in a long side direction of the support plate 310 in an area inside the support plate 310, and loads 350a and 350b respectively disposed on two end portions of the first and second extension plate 320a and 320b. In addition, a plurality of loads 351, 352, 353, and 354 are disposed at corner areas of the support plate 310.

As illustrated in FIG. 8D, the second piezoelectric plate 300 includes a support plate 310 having an approximately rectangular frame shape, first and second extension plates 320a and 320b formed in a long side direction of the support plate 310 from two opposite short sides of the support plate 310 and separated by a predetermined interval at the central area inside the support plate 310, and loads 350a and 350b formed on end portions of the first and second extension plates 320a and 320b. In addition, a plurality of loads 351, 352, 353, and 354 are disposed at corner areas of the support plate 310.

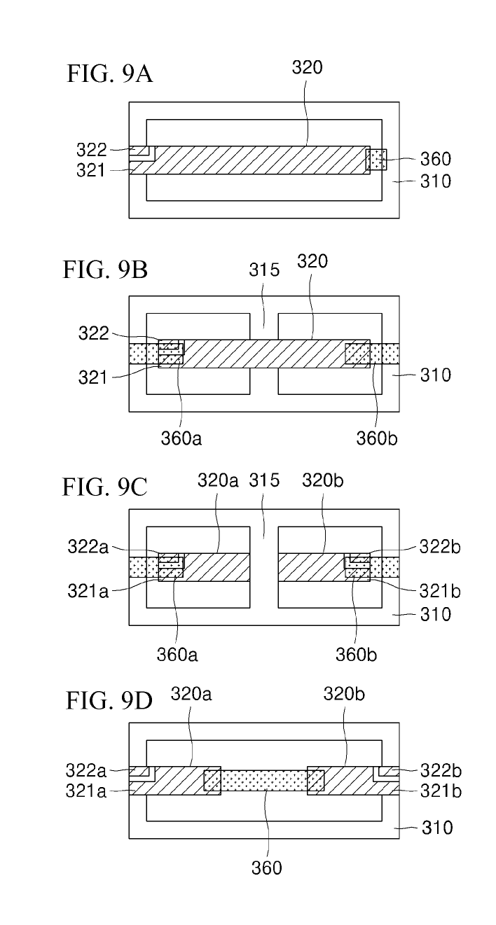

Furthermore, in a piezoelectric device of an embodiment, a vibration plate is disposed on at least one area of the second piezoelectric plate 300 to increase a vibration force and accordingly frequency characteristic may be diversely changed. The vibration plate may use a material such as a polymer, a metal, or silicon, the size thereof may be diversified, and accordingly the vibration force may be diversely realized. FIGS. 9A to 9D illustrate the second piezoelectric plate according to various modification examples of an embodiment.

As illustrated in FIG. 9A, the second piezoelectric plate 300 may include a support plate 310 having an approximately rectangular frame shape, an extension plate 320 disposed in a predetermined area of one short side of the support plate 310 in a long side direction of the support plate 310 in the support plate 310, and a vibration plate 360 between one end portion of the extension plate 320, which does not contact the support plate 310, and a short side of the support plate 310.

As illustrated in FIG. 9B, the second piezoelectric plate 300 includes a support plate 310 having an approximately rectangular frame shape and having a dummy plate 315 formed between one long side and the other long side opposite to each other, an extension plate 320 making a contact on the dummy plate 315 and disposed in a long side direction of the support plate 310 in an area inside the support plate 310, and vibration plates 360a and 350b respectively disposed between two end portions of the extension plate 320 and the support plate 310.

As illustrated in FIG. 9C, the second piezoelectric plate 300 includes a support plate 310 having an approximately rectangular frame shape and having a dummy plate 315 formed between one long side and the other long side opposite to each other, first and second extension plates 320a and 320b contacting two side surfaces of the dummy plate 315 and disposed in a long side direction of the support plate 310, and vibration plates 360a and 350b disposed between end portions of the first and second extension plate 320a and 320b and the support plate 310.

As illustrated in FIG. 9D, the second piezoelectric plate 300 includes a support plate 310 having an approximately rectangular frame shape, first and second extension plates 320a and 320b formed in a long side direction of the support plate 310 from two opposite short sides of the support plate 310 and separated by a predetermined interval at the central area inside the support plate 310, and a vibration plate 360 provided between end portions of the first and second extension plates 320a and 320b.

When such a piezoelectric device of an embodiment is used as a piezoelectric sound device, medium and higher frequency band characteristics as well as low frequency band characteristic can be improved.

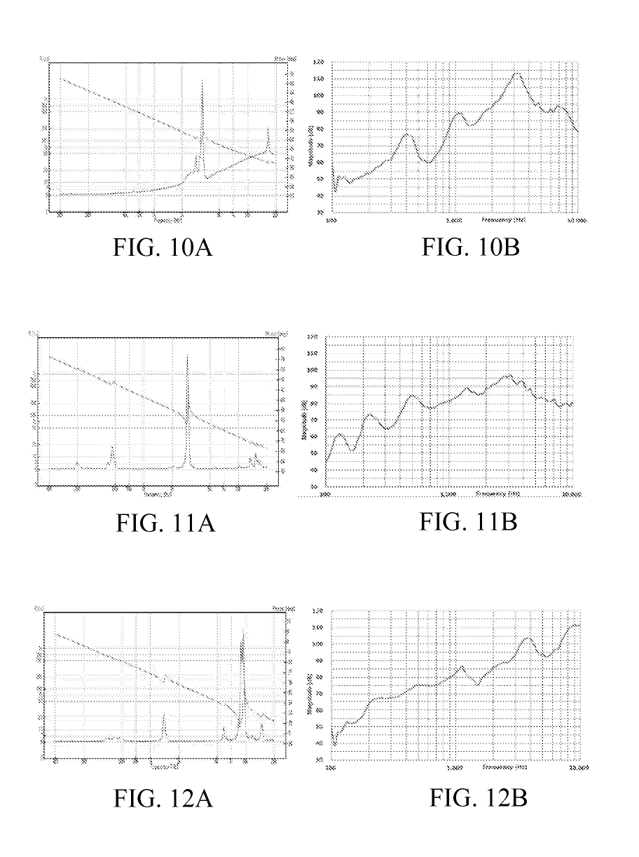

FIGS. 10A to 12B are graphs representing impedance and sound pressure characteristics of each part of a piezoelectric device according to an exemplary embodiment. In other words, FIGS. 10A and 10B are impedance and sound pressure characteristic graphs when only the extension plate of the second piezoelectric plate is used, FIGS. 11A and 11B are impedance and sound pressure characteristic graphs of the second piezoelectric plate, and FIGS. 12A and 12B are impedance and sound pressure characteristic graphs of the first piezoelectric plate.

The extension plate exhibits impedance characteristic at approximately 3.215 kHz as illustrated in FIG. 10A, and a resonant frequency of approximately 0.4 kHz and sound pressure characteristic of approximately 75 dB as illustrated in FIG. 10B. In addition, the second piezoelectric plate exhibits impedance characteristic at approximately 0.1889 kHz as illustrated in FIG. 11A, and a resonant frequency of approximately 0.15 kHz and sound pressure characteristic of approximately 60 dB as illustrated in FIG. 11B. In addition, the first piezoelectric plate exhibits impedance characteristic at approximately 1.3772 kHz as illustrated in FIG. 12A, and a resonant frequency of approximately 1.12 kHz and sound pressure characteristic of approximately 82 dB as illustrated in FIG. 12B. However, when the piezoelectric device is typically used as a sound device, a form of the first piezoelectric plate is used and since a resonant frequency is approximately 1.12 kHz at this point, sound pressure characteristic in a lower frequency band of approximately 1 kHz or lower gets lowered.

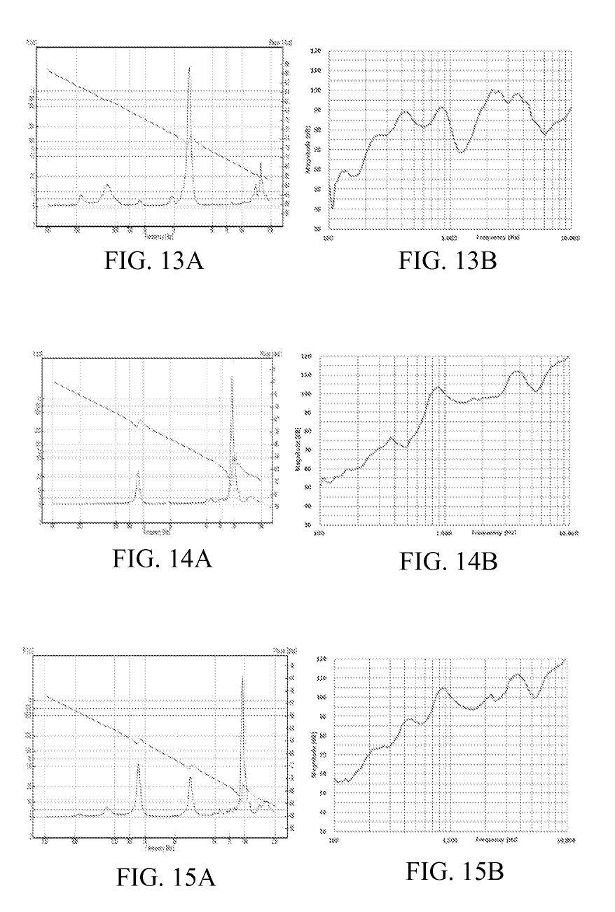

In addition, FIGS. 13A to 15B are graphs representing impedance and sound pressure characteristics of a piezoelectric device according to a signal application scheme according to an exemplary embodiment. In other words, FIGS. 13A and 13B are impedance and sound pressure characteristic graphs when a signal is applied only to the second piezoelectric plate is used, FIGS. 14A and 14B are impedance and sound pressure characteristic graphs when a signal is applied only to the first piezoelectric plate, and FIGS. 15A and 15B are impedance and sound pressure characteristic graphs when a signal is applied to the first and second piezoelectric plates.

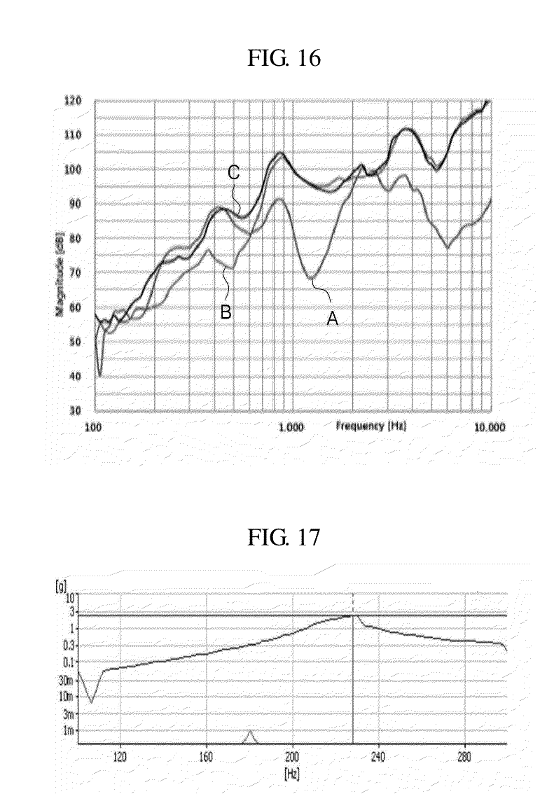

When the signal is applied only to the second piezoelectric plate, the piezoelectric device exhibits impedance characteristic at approximately 2.7425 kHz as illustrated in FIG. 13A, and a resonant frequency of approximately 0.4 kHz and sound pressure characteristic of approximately 89 dB as illustrated in FIG. 13B. In addition, when the signal is applied only to the first piezoelectric plate, the piezoelectric device exhibits impedance characteristic at approximately 0.836 kHz as illustrated in FIG. 14A, and a resonant frequency of approximately 0.9 kHz and sound pressure characteristic of approximately 104 dB as illustrated in FIG. 14B. In addition, when the signal is simultaneously applied to the first and second piezoelectric plates, the piezoelectric device exhibits impedance characteristic at approximately 0.8326 kHz as illustrated in FIG. 15A, and resonant frequencies of approximately 0.4 kHz and 0.9 kHz and sound pressure characteristics of approximately 88 dB and 100 dB as illustrated in FIG. 15B. Accordingly, when the piezoelectric device of embodiments is used as a piezoelectric sound device, resonant frequencies may be approximately 0.4 kHz and 0.9 kHz by simultaneously applying a signal to first and second piezoelectric plates, and accordingly sound pressure characteristic can be improved from a low frequency band to a high frequency band. In other words, as illustrated in FIG. 16, a case C where a signal is simultaneously applied to the first and second piezoelectric plate may improve sound pressure characteristics from the low frequency band to the high frequency band than a case A where a signal is applied to the second piezoelectric plate and a case B where a signal is applied to the first piezoelectric plate. In addition, FIG. 17 is a graph representing vibration characteristic of a piezoelectric device of an embodiment, which exhibits an output of approximately 2.2 G at a resonant frequency of 228 Hz.

A piezoelectric device according to embodiments includes at least two piezoelectric plates and at least two contact points to have at least two resonant frequencies. The piezoelectric device according to embodiments is disposed in an electronic device such as an auxiliary mobile device to operate as at least any one of the piezoelectric sound device and piezoelectric vibration device according to a signal provided from the electronic device. In other words, the piezoelectric device may operate as a piezoelectric sound device or a piezoelectric vibration device, or may simultaneously operate as the piezoelectric sound device and piezoelectric vibration device. Accordingly, an area occupied in the auxiliary mobile device can be reduced and accordingly the size and weight of the auxiliary mobile device can also be reduced by applying the piezoelectric device according to embodiments to the auxiliary mobile device in comparison to a typical technique that a sound device and vibration device are separately applied. In addition, when used as a piezoelectric sound device, the piezoelectric device can improve sound pressure characteristic from a lower frequency band to a higher frequency band.

Although the piezoelectric device and the electronic device including the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A piezoelectric device comprising:
at least two piezoelectric plates configured to comprise at two contact points,
wherein the at least two piezoelectric plates comprise at least two resonant frequencies.

2. The piezoelectric device of claim 2, wherein at least one intermediate plate is disposed between the at least two piezoelectric plates and the at least two piezoelectric plates are separated by a predetermined interval.

3. The piezoelectric device of claim 2, wherein the at least one intermediate plate is provided in a frame shape comprising an empty inner part.

4. The piezoelectric device of claim 2, wherein the at least two piezoelectric plates comprise at least two shapes.

5. The piezoelectric device of claim 4, wherein at least one first piezoelectric plate comprises one surface, another surface, and side surfaces therebetween, and
at least one second piezoelectric plate comprises a support plate comprising a shape of the intermediate plate and at least one extension plate formed from at least one area of the support plate to an inner area of the support plate.

6. The piezoelectric device of claim 5, wherein the extension plate comprises a protrusion part formed on a predetermined area thereof and the protrusion part is connected to at least one surface of the support plate.

7. The piezoelectric device of claim 5, further comprising a dummy plate disposed on a predetermined area on the support plate and the extension plate is connected to a top surface or side surface of the dummy plate.

8. The piezoelectric device of claim 5, further comprising a load disposed on at least one area on the extension plate.

9. The piezoelectric device of claim 5, further comprising a load disposed on at least one area on the support plate.

10. The piezoelectric device of claim 9, further comprising a vibration plate disposed between at least one area on the extension plate and at least one area on the support plate.

11. The piezoelectric device of claim 5, wherein the piezoelectric device operates as at least any one of a piezoelectric sound device or a piezoelectric vibration device according to a signal applied to the at least two piezoelectric plates.

12. The piezoelectric device of claim 11, wherein the signal is applied to the extension plate of the second piezoelectric plate or to the extension and support plates.

13. The piezoelectric device of claim 12, wherein the signal is applied to the intermediate plate to vibrate the intermediate plate.

14. An electronic device comprising:
a piezoelectric device configured to comprise at least two piezoelectric plates configured to comprise at two contact points,
wherein the at least two piezoelectric plates comprise at least two resonant frequencies and the piezoelectric device operates as at least any one of a piezoelectric sound device and a piezoelectric vibration device according to a signal applied to the at least two piezoelectric devices.

15. The electronic device of claim 14, wherein the electronic device is separated from a mobile terminal body to perform an auxiliary function of the mobile terminal, and is wearable.

16. The electronic device of claim 14, wherein at least one intermediate plate is disposed between the at least two piezoelectric plates and the at least two piezoelectric plates are separated by a predetermined interval.

17. The electronic device of claim 16, wherein at least a first piezoelectric plate is provided in a plate shape,
the at least one intermediate plate is provided in a frame shape comprising an empty inner part, and
at least one second piezoelectric plate comprises a support plate comprising a shape of the intermediate plate and at least one extension plate from at least one area from the support plate to an inner area of the support plate.

18. The electronic device of claim 17, further comprising a load disposed on at least one area on the extension plate.

19. The electronic device of claim 17, further comprising at least any one of a load provided in at least one area of the support plate, and a vibration plate provided between at least one area of the extension plate and at least one area of the support plate.

20. The electronic device of claim 19, wherein a signal is applied to at least any one of the extension plate and support plate of the second piezoelectric plate and a signal is further applied to the intermediate plate to vibrate the intermediate plate.
